(19) United States
(12) Patent Application Publication
(10) Pub. No.: US 2025/0169331 A1
(43) Pub. Date: May 22, 2025

(54) DISPLAY DEVICE, METHOD FOR MANUFACTURING THE SAME, AND ELECTRONIC DEVICE INCLUDING THE SAME

(71) Applicant: Samsung Display Co., LTD., Yongin-si (KR)

(72) Inventors: DONG-HUN KANG, Yongin-si (KR); SEONGSIK CHOI, Yongin-si (KR); YONG-WOO KIM, Yongin-si (KR); DONGHYEON LEE, Yongin-si (KR); JEONGIN LEE, Yongin-si (KR); JEONG-SEOP CHOI, Yongin-si (KR)

(73) Assignee: Samsung Display Co., LTD., Yongin-si (KR)

(21) Appl. No.: 18/950,952

(22) Filed: Nov. 18, 2024

(30) Foreign Application Priority Data
Nov. 21, 2023 (KR) 10-2023-0162795

(51) Int. Cl. H10K 59/80; H10K 102/00

(52) U.S. Cl. CPC H10K 59/8722; H10K 59/8793; H10K 2102/311

(57) ABSTRACT

A display device includes a display panel including pixels, a first component disposed on the display panel, a second component disposed on the first component, and an adhesive member between the first component and the second component and attaching the first component and the second component to each other. The adhesive member includes a first part having a first modulus and including a first adhesive material, a second part having a second modulus different from the first modulus and including a second adhesive material different from the first adhesive material, and a third part located between the first part and the second part, having a third modulus different from the first modulus and the second modulus, and including the first adhesive material and the second adhesive material.

### CROSS-REFERENCE TO RELATED APPLICATION(S)

This application claims priority to and benefits of Korean Patent Application No. 10-2023-0162795 under 35 U.S.C. § 119, filed on Nov. 21, 2023 in the Korean Intellectual Property Office (KIPO), the entire contents of which are hereby incorporated by reference.

### BACKGROUND

### 1. Technical Field

Embodiments relate to a display device that provides visual information and a method for manufacturing the same.

### 2. Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

In a manufacturing process of a display device, there is a method of applying an optically clear resin (OCR), bonding components, and curing the optically clear resin to attach the components disposed on a display panel.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device with reduced defects with respect to appearance and reliability.

Embodiments provide a method for manufacturing a display device having reduced defects with respect to appearance and reliability.

A display device according to an embodiment of the disclosure may include a display panel including pixels, a first component disposed on the display panel, a second component disposed on the first component, and an adhesive member between the first component and the second component and attaching the first component and the second component to each other. The adhesive member may include a first part having a first modulus and including a first adhesive material, a second part having a second modulus different from the first modulus and including a second adhesive material different from the first adhesive material, and a third part located between the first part and the second part, having a third modulus different from the first modulus and the second modulus, and including the first adhesive material and the second adhesive material.

In an embodiment, the first modulus may be equal to or greater than about 1 Mpa, and the second modulus may be in a range of about 0.03 Mpa to about 1 Mpa.

In an embodiment, each of the first modulus and the second modulus may be in a range of about 0.03 Mpa to about 1 Mpa.

In an embodiment, a thickness of the adhesive member may be in a range of about 30 micrometers (μm) to about 50 micrometers (μm).

In an embodiment, a thickness of the adhesive member may be in a range of about 35 micrometers (μm) to about 100 micrometers (μm).

In an embodiment, a refractive index of the third part may continuously change in a direction from the first part toward the second part or from the second part toward the first part.

In an embodiment, the first component may be a polarizing member, and the second component may be a window member.

In an embodiment, the first component may be a window member, and the second component may be a window protection layer protecting the window member.

In an embodiment, the display device may further include a polarizing member between the display panel and the first component. The first component may be a damping member protecting the display panel, and the second component may be a window member.

In an embodiment, the first adhesive material and the second adhesive material may include an optically transparent resin.

In an embodiment, the display panel may include a flexible foldable area, and a non-folding area adjacent to the foldable area.

A method for manufacturing a display device according to embodiments of the disclosure may include forming a display panel including pixels, attaching a first component on the display panel, simultaneously applying a first adhesive material and a second adhesive material different from the first adhesive material on the first component, bonding a second component to the first component, and forming an adhesive member by curing the first adhesive material and the second adhesive material applied on the first component. The adhesive member may include a first part having a first modulus and including the first adhesive material, a second part having a second modulus different from the first modulus and including the second adhesive material different from the first adhesive material, and a third part located between the first part and the second part, having a third modulus different from the first modulus and the second modulus, and including the first adhesive material and the second adhesive material.

In an embodiment, in an overlapping area where the third part is formed, an amount of application of the first adhesive material may gradually change in a direction from a first area where the first part is formed toward a second area where the second part is formed, and an amount of application of the second adhesive material may gradually change in a direction from the second area toward the first area.

In an embodiment, the first modulus may be equal to or greater than about 1 Mpa, and the second modulus may be in a range of about 0.03 Mpa to about 1 Mpa.

In an embodiment, each of the first modulus and the second modulus may be in a range of about 0.03 Mpa to about 1 Mpa.

In an embodiment, a refractive index of the third part may continuously change in a direction from the first part toward the second part or from the second part toward the first part.

In an embodiment, the first component may be a polarizing member, and the second component may be a window member.

In an embodiment, the first component may be a window member, and the second component may be a window protection layer protecting the window member.

In an embodiment, the method may further include disposing a polarizing member between the display panel and the first component, the first component may be a damping member protecting the display panel, and the second component may be a window member.

In an embodiment, the display panel may include a flexible foldable area, and a non-folding area adjacent to the foldable area.

An electronic device according to an embodiment of the disclosure may include a display device and a processor which controls the display device. The display device includes: a display panel including pixels, a first component disposed on the display panel, a second component disposed on the first component, and an adhesive member between the first component and the second component and attaching the first component and the second component to each other, the adhesive member including: a first part having a first modulus and including a first adhesive material, a second part having a second modulus different from the first modulus and including a second adhesive material different from the first adhesive material, and a third part located between the first part and the second part, having a third modulus different from the first modulus and the second modulus, and including the first adhesive material and the second adhesive material.

A display device according to embodiments of the disclosure may include an adhesive member attaching a first component and a second component disposed on a display panel, and including a first part having a first modulus and including a first adhesive material, a second part having a second modulus different from the first modulus and including a second adhesive material different from the first adhesive material, and a third part located between the first part and the second part, having a third modulus different from the first modulus and the second modulus, and including the first adhesive material and the second adhesive material. Accordingly, appearance defects of the second component attached to the first component may be reduced. In addition, reliability defects of the display device may be reduced.

### BRIEF DESCRIPTION OF THE DRAWINGS

Illustrative, non-limiting embodiments will be more clearly understood from the following detailed description in conjunction with the accompanying drawings.

FIG. 1 is a schematic plan view illustrating a display device according to an embodiment of the disclosure.

FIGS. 2 and 3 are schematic cross-sectional views illustrating the display device of FIG. 1 in a folded state.

FIG. 4 is a schematic cross-sectional view illustrating an example of a cross-section taken along line I-I′ of FIG. 1.

FIG. 5 is an enlarged schematic cross-sectional view of area A of FIG. 4.

FIGS. 6, 7, 8, and 9 are schematic plan views illustrating embodiments of a first support member of FIG. 4.

FIG. 10 is a schematic cross-sectional view illustrating an adhesive member attaching a first component and a second component of a display device according to an embodiment of the disclosure.

FIG. 11 is a schematic view illustrating the change in a refractive index according to a position of the adhesive member of FIG. 10.

FIGS. 12, 13, and 14 are schematic cross-sectional views illustrating steps of a method for manufacturing a display device according to an embodiment of the disclosure.

FIG. 15 is a schematic cross-sectional view illustrating another example of a cross-section taken along line I-I′ of FIG. 1.

FIG. 16 is a schematic block diagram illustrating an electronic device according to an embodiment of the present disclosure.

### DETAILED DESCRIPTION OF THE EMBODIMENTS

Hereinafter, a display device and a method for manufacturing the same according to embodiments of the disclosure will be explained in detail with reference to the accompanying drawings. The same reference numerals are used for the same components in the drawings, and redundant descriptions of the same components will be omitted.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or “to not overlap” another element, this may include that the elements are spaced apart from each other, offset from each other, or set aside from each other or any other suitable term as would be appreciated and understood by those of ordinary skill in the art.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

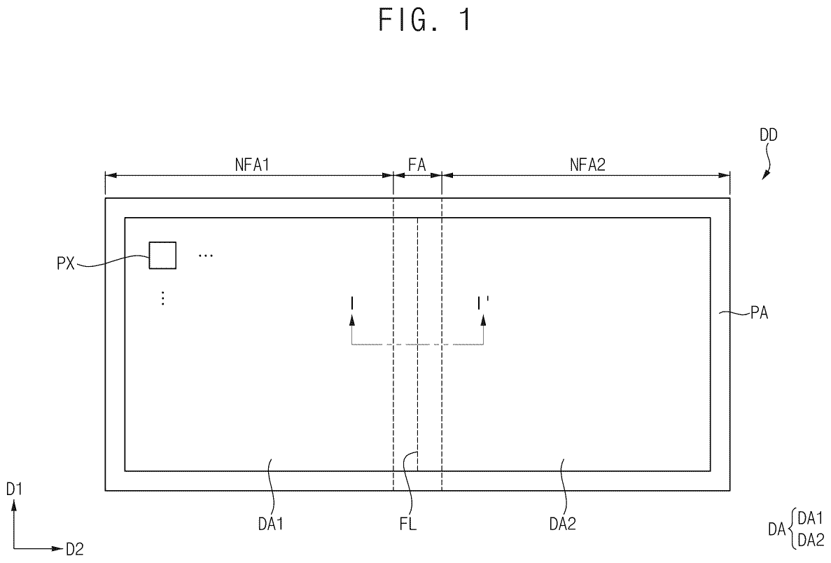

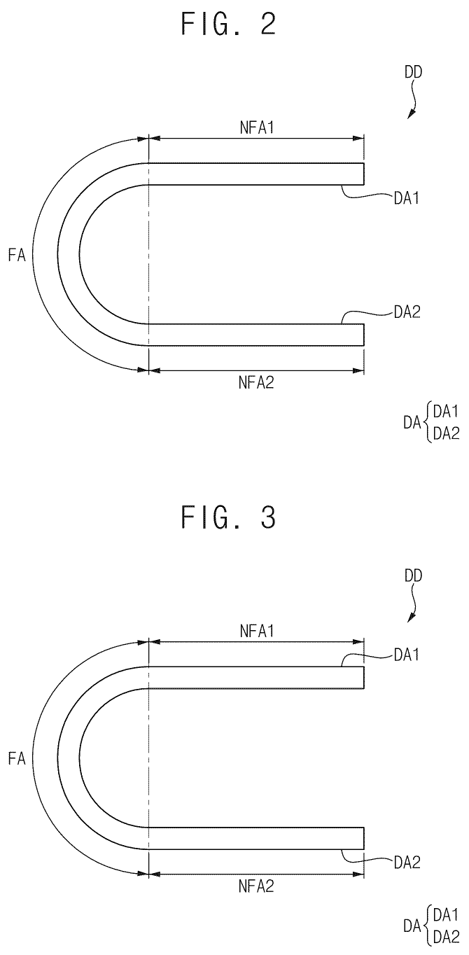

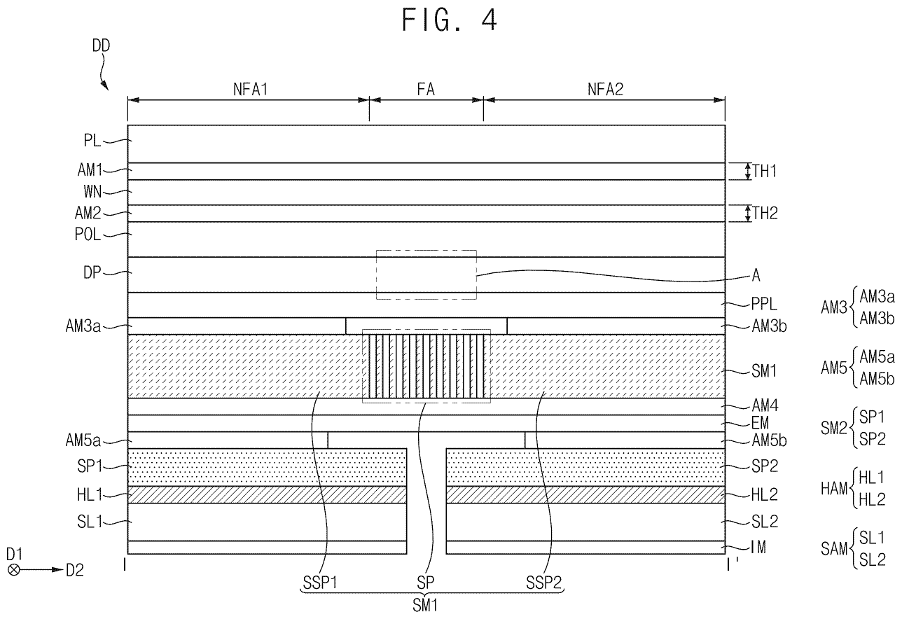

FIG. 1 is a schematic plan view illustrating a display device according to an embodiment of the disclosure. FIGS. 2 and 3 are schematic cross-sectional views illustrating the display device of FIG. 1 in a folded state.

Referring to FIGS. 1, 2, and 3, a display device DD according to an embodiment of the disclosure may include a display area DA and a peripheral area PA. The peripheral area PA may be located around the display area DA. For example, the peripheral area PA may surround at least a part of the display area DA.

Pixels PX may be disposed in the display area DA. Each of the pixels PX may emit light. As each of the pixels PX emits light, the display area DA may display an image. For example, each of the pixels PX may include a transistor that generates a driving current and a light-emitting element electrically connected to the transistor.

The pixels PX may be arranged in a matrix form along a first direction D1 and a second direction D2 crossing the first direction D1 in a plan view. For example, the first direction D1 may be perpendicular to the second direction D2.

A driver may be disposed in a peripheral area PA. The driver may provide signals and/or voltages to the pixels PX. For example, the driver may include a data driver, a gate driver, and the like. The peripheral area PA may not display images.

At least a part of the display device DD may be flexible and may be folded at a flexible part (i.e., a foldable area FA). That is, the display area DA may include the foldable area FA that can be bent by an external force so as to fold the display device DD, and first and second non-folding areas NFA1 and NFA2 adjacent to at least one side of the foldable area FA and not folded. For example, the foldable area FA may have a folding line FL extending along the first direction D1. Here, an area that does not fold is referred to as a non-folding area, but this is for convenience of explanation. The expression “non-folding” includes not only cases that are rigid due to lack of flexibility, but also cases that are flexible but do not fold because the flexibility is smaller than the foldable area FA.

The display area DA may be divided into a first display area DA1 and a second display area DA2. Specifically, the first display area DA1 and the second display area DA2 may be adjacent to each other in the second direction D2. The first display area DA1 and the second display area DA2 may be continuously connected to substantially form a display area DA. For example, in case that the display area DA is folded along the folding line FL, as shown in FIG. 2, the display device DD may have an in-folding structure such that the first display area DA1 and the second display area DA2 face each other. In other embodiments, in case that the display area DA is folded along the folding line FL, as shown in FIG. 3, the display device DD may have an out-folding structure in which the first display area DA1 and the second display area DA2 are disposed on an outside.

In FIG. 1, the display device DD is shown as having one foldable area FA, but the display device DD according to an embodiment of the disclosure is not limited to having one foldable area FA. For example, the display device DD may be folded multiple times or may have multiple foldable areas to implement a rollable display device.

FIG. 4 is a schematic cross-sectional view illustrating an example of a cross-section taken along line I-I′ of FIG. 1. For example, FIG. 4 may show the display device DD in an unfolded state.

Referring to FIGS. 1 and 4, the display device DD according to an embodiment of the disclosure may include a window protection layer PL, a first adhesive member AM1, a window member WN, a second adhesive member AM2, a polarizing member POL, a display panel DP, a third adhesive member AM3, a first support member SM1, a fourth adhesive member AM4, an elastic member EM, a fifth adhesive member AM5, a second support member SM2, a heat dissipation member HAM, an impact absorbing member SAM, and an insulating member IM.

The polarizing member POL may be disposed on the display panel DP. As the display device DD includes a foldable area FA, the display panel DP may also have the foldable area FA. The display panel DP may include pixels (e.g., pixels PX of FIG. 1) that generate light. The polarizing member POL may block external light incident on the display panel DP from the outside.

The window member WN may be disposed on the polarizing member POL. The window member WN may protect the display panel DP. The window member WN may have a transparent part corresponding to the display area DA. The window member WN may include a polymer material, a glass thin film, and the like to enable bending.

For example, the window member WN may include ultra-thin glass (UTG). The ultra-thin tempered glass may be strengthened and have a predetermined or selected stress profile inside. The ultra-thin tempered glass may better prevent the occurrence of cracks, propagation of cracks, and breakage due to external impacts than before strengthening. The ultra-thin tempered glass may have various stresses in each area through a strengthening process.

For example, the ultra-thin tempered glass of the window member WN may be thin film glass that has been chemically strengthened to have strong strength. However, embodiments of the disclosure are not limited to this configuration, and the ultra-thin tempered glass of the window member WN may be thin film glass that has been thermally strengthened.

In case that glass is composed of an ultra-thin film or a thin film, the glass may have flexible characteristics and may be bent, folded, or rolled.

For example, the window member WN may include glass such as soda lime glass, alkali alumino silicate glass, borosilicate glass, lithium alumina silicate glass, and the like. These can be used alone or in combination with each other. However, embodiments of the disclosure are not limited thereto, and the window member WN may include various types of glass.

The window protection layer PL may be disposed on the window member WN. The window protection layer PL may perform at least one of the functions of preventing the window member WN from scattering, absorbing shock, preventing scratches, preventing fingerprints, and preventing glare. The window protection layer PL may include a transparent polymer film. For example, the window protection layer PL may include a transparent polymer film such as epoxy resin, polyurethane, polyester, polyethylene terephthalate, polyethylene naphthalate, polyimide, polyarylate, polycarbonate, polymethyl methacrylate, ethyl vinyl acetate, and polyamide resin. These can be used alone or in combination with each other.

The first adhesive member AM1 may be disposed between the window member WN and the window protection layer PL. The first adhesive member AM1 may attach the window member WN and the window protection layer PL to each other. For example, the first adhesive member AM1 may include optical clear adhesive (OCA) or optical clear resin (OCR). In an embodiment, the first adhesive member AM1 may include an optically transparent resin.

For example, a thickness TH1 of the first adhesive member AM1 may have a range from about 30 micrometers (μm) to about 50 micrometers (μm).

The second adhesive member AM2 may be disposed between the polarizing member POL and the window member WN. The second adhesive member AM2 may attach the polarizing member POL and the window member WN to each other. For example, the second adhesive member AM2 may include an optically clear adhesive or an optically transparent resin. In an embodiment, the second adhesive member AM2 may include an optically transparent resin.

For example, a thickness TH2 of the second adhesive member AM2 may have a range from about 35 micrometers (μm) to about 100 micrometers (μm).

In an embodiment, at least one of the first adhesive member AM1 and the second adhesive member AM2 may include different types of adhesive materials. A detailed description of this will be provided later with reference to FIG. 10.

The first support member SM1 may be disposed under the display panel DP. The first support member SM1 may serve to support the display panel DP. The first support member SM1 may serve to assist in folding the display panel DP. The first support member SM1 may prevent foreign substances from entering the display panel DP from the outside. The first support member SM1 may radiate or disperse heat generated in the display panel DP.

The rigidity of the first support member SM1 may be greater than the rigidity of the display panel DP. Accordingly, the first support member SM1 may prevent the display panel DP from being deformed due to a user's external force and the like.

For example, the first support member SM1 may include a first support part SSP1, a second support part SSP2, and a stretchable part SP. The stretchable part SP may be located between the first support part SSP1 and the second support part SSP2. The stretchable part SP may overlap the foldable area FA, the first support part SSP1 may overlap the first non-folding area NFA1, and the second support part SSP2 may overlap the second non-folding area NFA2. Accordingly, the first and second support parts SSP1 and SSP2 may support the part of the display panel DP overlapping the first and second non-folding areas NFA1 and NFA2, and the stretchable part SP may help the display panel DP be folded.

The stretchable part SP may have elasticity in response to folding and unfolding of the display device DD. However, although FIG. 4 shows only one stretchable part SP, embodiments of the disclosure are not limited thereto. For example, the stretchable part SP may include multiple stretchable parts SP. A detailed description of the stretchable part SP will be described later.

In an embodiment, the first support member SM1 may include an alloy. For example, the first support member SM1 may include stainless steel (SUS), magnesium alloy, and the like. In another embodiment, the first support member SM1 may include glass or plastic. For example, the first support member SM1 may include carbon fiber reinforced plastic (CFRP), glass fiber reinforced plastic (GFRP), and the like. However, embodiments of the disclosure are not limited to this configuration, and the first support member SM1 may include various materials.

A display panel protection layer PPL may be disposed under the display panel DP. The display panel protection layer PPL may protect a lower part of the display panel DP. The display panel protection layer PPL may include a flexible plastic material. For example, the display panel protection layer PPL may include polyethylene terephthalate, and the like. However, the material included in the display panel protection layer PPL is not limited to this configuration, and the display panel protection layer PPL may include other flexible plastic materials.

The third adhesive member AM3 may be disposed between the first support member SM1 and the display panel protection layer PPL. The third adhesive member AM3 may include a first adhesive layer AM3a and a second adhesive layer AM3b spaced apart from each other in the second direction D2. Each of the first adhesive layer AM3a and the second adhesive layer AM3b may not overlap the foldable area FA. The third adhesive member AM3 may attach the display panel protection layer PPL and the first support member SM1 to each other. For example, the third adhesive member AM3 may include an optically clear adhesive or an optically transparent resin.

The elastic member EM may be disposed under the first support member SM1. Specifically, the elastic member EM may be disposed between the first support member SM1 and the second support member SM2. The elastic member EM may partially overlap the foldable area FA. While the display device DD repeatedly performs folding and unfolding, the elastic member EM may prevent foreign substances from penetrating into the stretchable part SP. While the display device DD repeatedly performs folding and unfolding, the elastic member EM may be stretched and contracted so as not to expose the stretchable part SP.

For example, the elastic member EM may include an elastic polymer having a relatively high elastic force or a relatively high restoring force. For example, the elastic member EM may include an elastic material such as silicone, urethane, thermoplastic polyurethane (TPU), and the like. These can be used alone or in combination with each other.

The fourth adhesive member AM4 may be disposed between the first support member SM1 and the elastic member EM. The fourth adhesive member AM4 may attach the first support member SM1 and the elastic member EM to each other. For example, the fourth adhesive member AM4 may include an optically clear adhesive or an optically transparent resin.

The second support member SM2 may be disposed under the first support member SM1. The second support member SM2 may include a first support plate SP1 and a second support plate SP2 spaced apart from each other. Specifically, the first support plate SP1 and the second support plate SP2 may be spaced apart from each other in the second direction D2. Each of the first support plate SP1 and the second support plate SP2 may at least partially overlap the foldable area FA.

For example, in case that the display device DD is folded, a distance between the first support plate SP1 and the second support plate SP2 may increase. The second support member SM2 may prevent the stretchable part SP of the first support member SM1 from being pressed.

In an embodiment, the second support member SM2 may include an alloy. For example, the second support member SM2 may include stainless steel, magnesium alloy, and the like. In another embodiment, the second support member SM2 may include glass or plastic. For example, the second support member SM2 may include carbon fiber reinforced plastic, glass fiber saponified plastic, and the like. However, embodiments of the disclosure are not limited to this configuration, and the second support member SM2 may include various materials.

The fifth adhesive member AM5 may be disposed between the elastic member EM and the second support member SM2. The fifth adhesive member AM5 may include a first adhesive layer AM5a and a second adhesive layer AM5b spaced apart from each other in the second direction D2. The first adhesive layer AM5a and the second adhesive layer AM5b may not overlap the foldable area FA. The first adhesive layer AM5a may attach the elastic member EM and the first support plate SP1 to each other, and the second adhesive layer AM5b may attach the elastic member EM and the second support plate SP2. For example, the fifth adhesive member AM5 may include an optically clear adhesive or an optically transparent resin.

The heat dissipation member HAM may be disposed under the second support member SM2. The heat dissipation member HAM may include a first heat dissipation layer HL1 and a second heat dissipation layer HL2 spaced apart from each other. Specifically, the first heat dissipation layer HL1 and the second heat dissipation layer HL2 may be spaced apart from each other in the second direction D2. Each of the first heat dissipation layer HL1 and the second heat dissipation layer HL2 may at least partially overlap the foldable area FA.

The heat dissipation member HAM may include a material with high thermal conductivity. For example, the heat dissipation member HAM may include aluminum (Al), copper (Cu), and the like. These can be used alone or in combination with each other. In other embodiments, the heat dissipation member HAM may be omitted.

The shock absorbing member SAM may be disposed under the heat dissipating member HAM. The shock absorbing member SAM may include a first cushion layer SL1 and a second cushion layer SL2 spaced apart from each other. Specifically, the first cushion layer SL1 and the second cushion layer SL2 may be spaced apart from each other in the second direction D2. Each of the first cushion layer SL1 and the second cushion layer SL2 may partially overlap the foldable area FA.

The shock absorbing member SAM may protect the display panel DP from external shock. The shock absorbing member SAM may include a material having flexibility so that the display device DD can be easily folded. For example, the shock absorbing member SAM may include a foam-type material such as polyurethane foam, polystyrene foam, and the like. These can be used alone or in combination with each other.

The insulating member IM may be disposed under the shock absorbing member SAM. For example, the insulating member IM may be formed in the form of a film or tape. The insulating member IM may prevent rattling from occurring in the display device DD.

As described above, since the display device DD according to an embodiment of the disclosure can be folded or unfolded, each of the window protection layer PL, the window member WN, the polarizing member POL, the display panel DP, and the first support members SM1 may have flexibility.

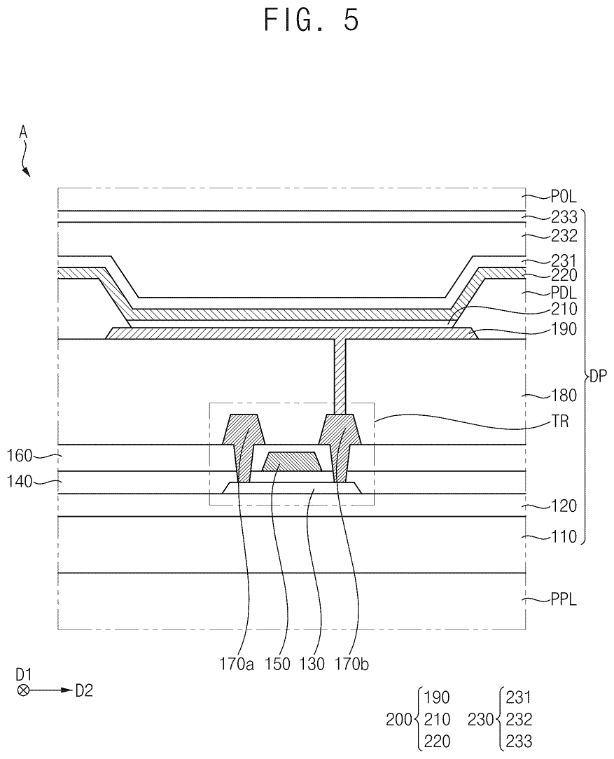

FIG. 5 is an enlarged schematic cross-sectional view of area A of FIG. 4. For example, FIG. 5 is an enlarged cross-sectional view of a part of the display panel DP of FIG. 4.

Referring to FIG. 5, the display panel DP of the display device DD according to an embodiment of the disclosure may include a substrate 110, a buffer layer 120, a gate insulating layer 140, a transistor TR, an interlayer insulating layer 160, a planarization layer 180, a pixel defining layer PDL, a light-emitting element 200, and an encapsulation layer 230.

Here, the transistor TR may include an active layer 130, a gate electrode 150, a source electrode 170a, and a drain electrode 170b, the light-emitting element 200 may include a lower electrode 190, a light-emitting layer 210, and an upper electrode 220, and the encapsulation layer 230 may include a first thin film encapsulation layer 231, a second thin film encapsulation layer 232, and a third thin film encapsulation layer 233.

The substrate 110 may include a transparent material or an opaque material. The substrate 110 may include a flexible transparent resin substrate. An example of the transparent resin substrate that can be used as the substrate 110 may include a polyimide substrate. In other embodiments, the substrate 110 may include a quartz substrate, a synthetic quartz substrate, a calcium fluoride substrate, a soda-lime glass substrate, an alkali-free glass substrate, and the like. These can be used alone or in combination with each other.

The buffer layer 120 may be disposed on the substrate 110. The buffer layer 120 may prevent metal atoms or impurities from diffusing from the substrate 110 into the transistor TR. For example, the buffer layer 120 may include an inorganic material such as silicon oxide, silicon nitride, and the like. These can be used alone or in combination with each other.

The active layer 130 may be disposed on the buffer layer 120. The active layer 130 may include a metal oxide semiconductor, an inorganic semiconductor (e.g., amorphous silicon, polysilicon), or an organic semiconductor. The active layer 130 may have a source region, a drain region, and a channel region located between the source region and the drain region. The source region and the drain region may be doped with impurities.

The gate insulating layer 140 may be disposed on the buffer layer 120. The gate insulating layer 140 may sufficiently cover the active layer 130 on the substrate 110, and may have a substantially flat upper surface without creating steps around the active layer 130. In other embodiments, the gate insulating layer 140 may cover the active layer 130 on the substrate 110 and may be disposed along the profile of the active layer 130 with a uniform thickness. For example, the gate insulating layer 140 may include silicon oxide (SiOₓ), silicon nitride (SiNₓ), silicon carbide (SiCₓ), silicon oxynitride (SiOₓN_{y}), silicon oxycarbide (SiOₓC_{y}), and the like. These can be used alone or in combination with each other.

The gate electrode 150 may be disposed on the gate insulating layer 140. The gate electrode 150 may overlap the channel region of the active layer 130. For example, the gate electrode 150 may include metal, alloy, metal nitride, conductive metal oxide, transparent conductive material, and the like. These can be used alone or in combination with each other.

The interlayer insulating layer 160 may be disposed on the gate insulating layer 140. The interlayer insulating layer 160 may sufficiently cover the gate electrode 150 on the substrate 110 and may have a substantially flat upper surface without creating steps around the gate electrode 150. In other embodiments, the interlayer insulating layer 160 may cover the gate electrode 150 on the substrate 110 and may be disposed along the profile of the gate electrode 150 with a uniform thickness. For example, the interlayer insulating layer 160 may include silicon oxide, silicon nitride, silicon carbide, silicon oxynitride, silicon oxycarbide, and the like. These can be used alone or in combination with each other.

The source electrode 170a and the drain electrode 170b may be disposed on the interlayer insulating layer 160. The source electrode 170a may be connected to the source region of the active layer 130 through a contact hole penetrating a first part of the gate insulating layer 140 and the interlayer insulating layer 160, and the drain electrode 170b may be connected to the drain region of the active layer 130 through a contact hole penetrating a second part of the gate insulating layer 140 and the interlayer insulating layer 160. For example, each of the source electrode 170a and the drain electrode 170b may include metal, alloy, metal nitride, conductive metal oxide, transparent conductive material, and the like. These can be used alone or in combination with each other.

Accordingly, the transistor TR including the active layer 130, the gate electrode 150, the source electrode 170a, and the drain electrode 170b may be disposed in the display area DA on the substrate 110.

The planarization layer 180 may be disposed on the interlayer insulating layer 160. The planarization layer 180 may sufficiently cover the source electrode 170a and the drain electrode 170b. The planarization layer 180 may include organic materials and/or inorganic materials. In an embodiment, the planarization layer 180 may include an organic material. For example, the planarization layer 180 may include an organic material such as polyimide-based resin, photoresist, polyacryl-based resin, polyimide-based resin, siloxane-based resin, and the like. These can be used alone or in combination with each other.

The lower electrode 190 may be disposed on the planarization layer 180. The lower electrode 190 may be connected to the drain electrode 170b (or source electrode 170a) through a contact hole penetrating the planarization layer 180. For example, the lower electrode 190 may include metal, alloy, metal nitride, conductive metal oxide, transparent conductive material, and the like. These can be used alone or in combination with each other. The lower electrode 190 may be defined as an anode electrode.

The pixel defining layer PDL may be disposed on the planarization layer 180. An opening exposing at least a part of the upper surface of the lower electrode 190 may be defined in the pixel defining layer PDL. The pixel defining layer PDL may include organic materials and/or inorganic materials. For example, the pixel defining layer PDL may include an organic material such as polyimide resin, photoresist, polyacrylic resin, polyamide resin, siloxane resin, and the like. These can be used alone or in combination with each other.

The light-emitting layer 210 may be disposed on the lower electrode 190. The light-emitting layer 210 may be disposed on the lower electrode 190 exposed by the opening. The light-emitting layer 210 may be formed using at least one of light-emitting materials capable of emitting red light, green light, and blue light. In other embodiments, the light-emitting layer 210 may emit white light as a whole by stacking multiple light emitting materials capable of generating different color lights, such as red light, green light, and blue light.

The upper electrode 220 may be disposed on the pixel defining layer PDL and the light emitting layer 210. For example, the upper electrode 220 may include metal, alloy, metal nitride, conductive metal oxide, transparent conductive material, and the like. These can be used alone or in combination with each other. The upper electrode 220 may be defined as a cathode electrode.

Accordingly, the light-emitting element 200 including the lower electrode 190, the light-emitting layer 210, and the upper electrode 220 may be disposed in the display area DA on the substrate 110. The light-emitting element 200 may be electrically connected to the transistor TR.

The first thin film encapsulation layer 231 may be disposed on the upper electrode 220. The first thin film encapsulation layer 231 may prevent the light-emitting layer 210 from being deteriorated due to penetration of moisture, oxygen, and the like. The first thin film encapsulation layer 231 may also perform a function of protecting the display panel DP from external shock. For example, the first thin film encapsulation layer 231 may include flexible inorganic materials.

The second thin film encapsulation layer 232 may be disposed on the first thin film encapsulation layer 231. The second thin film encapsulation layer 232 may improve the flatness of the display panel DP and protect the display panel DP. For example, the second thin film encapsulation layer 232 may include flexible organic materials.

The third thin film encapsulation layer 233 may be disposed on the second thin film encapsulation layer 232. The third thin film encapsulation layer 233, together with the first thin film encapsulation layer 231, may prevent the light-emitting layer 210 from being deteriorated due to penetration of moisture, oxygen, and the like. The third thin film encapsulation layer 233 may also perform a function of protecting the display panel DP together with the first thin film encapsulation layer 231 and the second thin film encapsulation layer 232 from external shock. For example, the third thin film encapsulation layer 233 may include flexible inorganic materials.

However, referring again to FIGS. 1, 2, 3, 4, and 5, the display device DD of the disclosure is described as being an organic light emitting display device, but embodiments of the disclosure are not limited thereto. For example, the display device DD may include liquid crystal display devices (LCD), field emission display devices (FED), plasma display devices (PDP), an electrophoretic display device (EPD) or quantum dot display device.

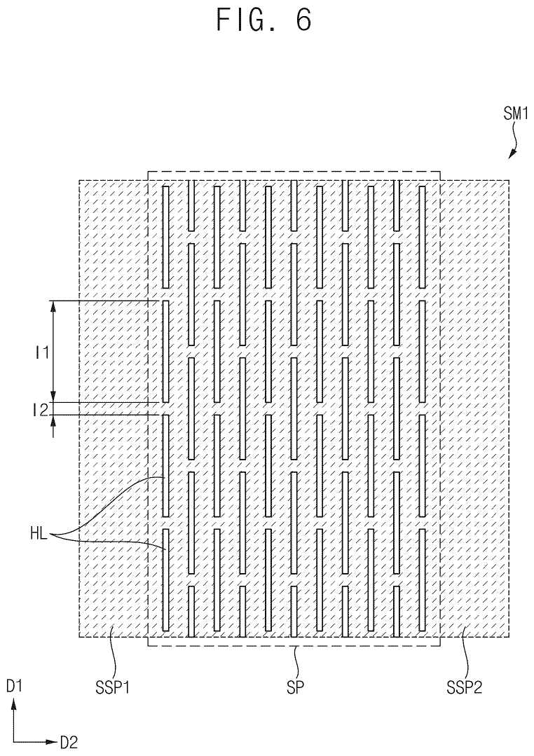

FIGS. 6, 7, 8, and 9 are schematic plan views illustrating embodiments of a first support member (SM1, SM1′, SM1″, SM1′″) of FIG. 4.

Referring to FIGS. 6, 7, 8, and 9, as described above, the first support member SM1 may include the first support part SSP1, the second support part SSP2, and the stretchable part SP (SP′, SP″, SP′″). In an embodiment, openings HL may be defined in the stretchable part SP. For example, each of the openings HL may have a planar shape of any of rectangular, diamond, oval, wavy, and rectangular with rounded corners.

Referring again to FIG. 6, each of the openings HL may extend in the first direction D1. That is, a long axis of each of the openings HL may be parallel to the first direction D1.

The openings HL may have the same planar shape. For example, each of the openings HL may have a rectangular planar shape. In this case, each of the openings HL may have a predetermined or selected length 11. The openings HL arranged in the same row may be spaced apart by a predetermined or selected distance 12. The openings HL arranged in the same row may be disposed in parallel with or in a staggered manner from the openings HL arranged in another adjacent row.

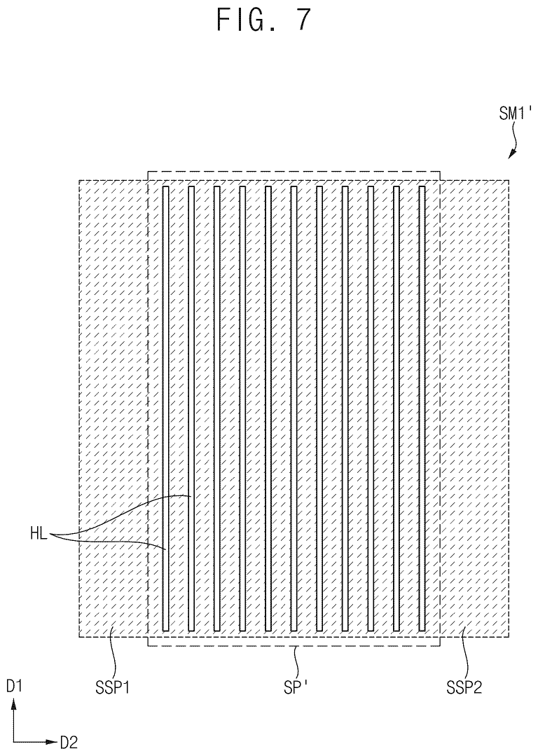

Referring again to FIG. 7, each of the openings HL may extend in the first direction D1. That is, a long axis of each of the openings HL may be parallel to the first direction D1. The openings HL may be arranged to be spaced apart from each other along the second direction D2.

The openings HL may have the same planar shape. For example, each of the openings HL may have a rectangular planar shape and extend in the first direction D1. Only one opening HL may be arranged in one column among the openings HL.

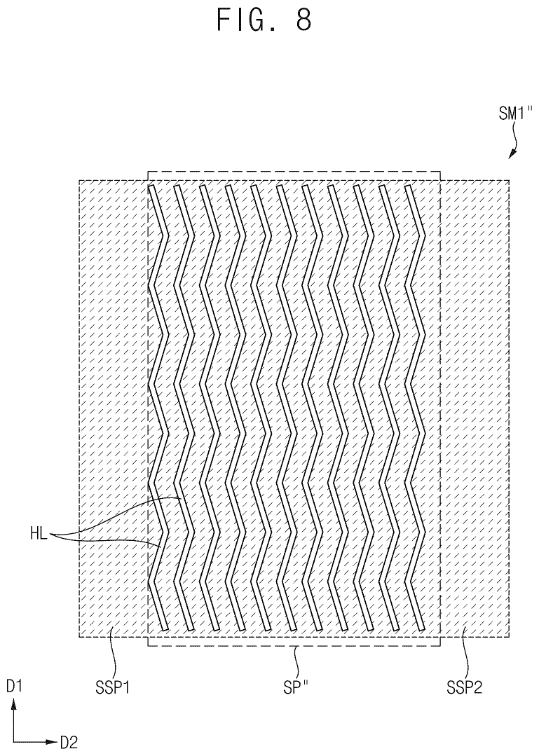

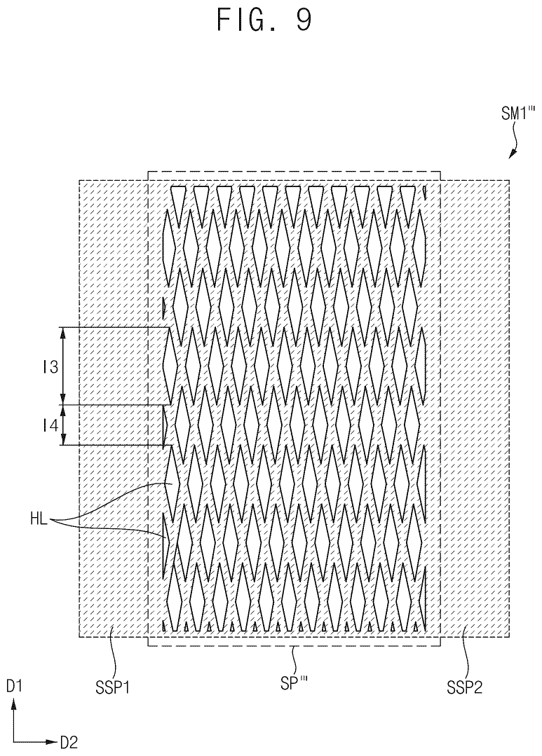

Referring again to FIG. 8, each of the openings HL may extend in the first direction D1. The openings HL may be arranged to be spaced apart from each other along the second direction D2.

The openings HL may have the same planar shape. For example, each of the openings HL may have a wave-like planar shape. Only one opening HL may be arranged in one column among the openings HL.

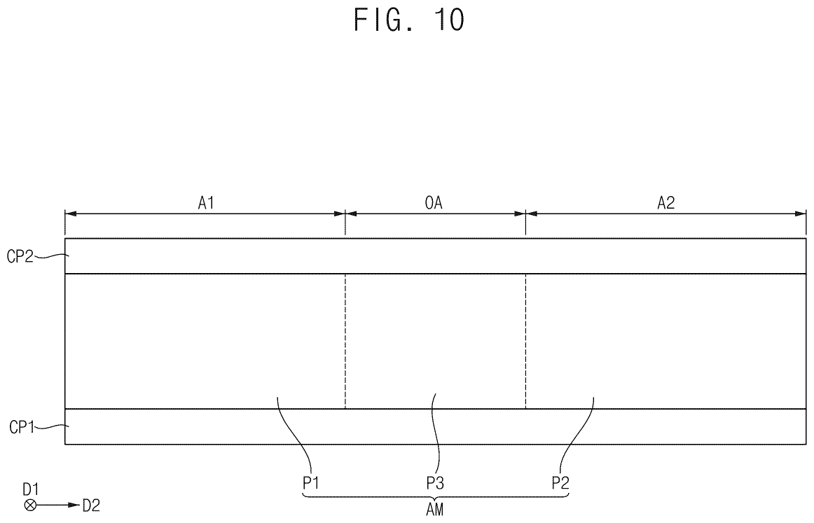

Referring again to FIG. 9, the openings HL may have the same planar shape. For example, each of the openings HL may have a diamond-shaped planar shape. In this case, each of the openings HL may have a predetermined or selected length 13. The openings HL arranged in the same row may be spaced apart by a predetermined or selected distance 14. The openings HL arranged in the same row may be disposed in parallel with or in a staggered manner from the openings HL arranged in another adjacent row.

However, embodiments are not limited to this configuration, and the shape and size of each of the openings HL may vary. For example, each of the openings HL may have a planar shape of a rectangular shape with rounded corners or an oval shape.

FIG. 10 is a schematic cross-sectional view illustrating an adhesive member attaching a first component and a second component of a display device according to an embodiment of the disclosure.

Referring to FIGS. 1, 4, and 10, the display device DD may include a first component CP1 disposed on the display panel DP, and a second component CP2 disposed on the first component CP1, and an adhesive member AM attaching the first component CP1 and the second component CP2.

The adhesive member AM may include a first part P1, a second part P2, and a third part P3 located between the first part P1 and the second part P2. The first part P1 may be formed in a first area A1, the second part P2 may be formed in a second area A2, and the third part P3 may be formed in an overlapping area OA. The overlapping area OA may be located between the first area A1 and the second area A2.

In an embodiment, the adhesive member AM may include different adhesive materials. That is, the adhesive member AM may include a first adhesive material and a second adhesive material different from the first adhesive material. In other words, the first adhesive material and the second adhesive material may be of different types. The first adhesive material and the second adhesive material may include an optically transparent resin.

In an embodiment, the first part P1 of the adhesive member AM may include the first adhesive material, the second portion P2 of the adhesive member AM may include the second adhesive material, and the third portion P3 of the adhesive member AM may include the first adhesive material and the second adhesive material. That is, the first part P1 and the second part P2 of the adhesive member AM may include only one adhesive material, and the third part P3 of the adhesive member AM may include different types of adhesive materials mixed together.

For example, a monomer that is the main component of the first adhesive material and a monomer that is the main component of the second adhesive material may be substantially the same or similar. In this case, the first adhesive material and the second adhesive material may be well mixed in the third part P3 of the adhesive member AM. However, embodiments of the disclosure are not limited thereto.

The first adhesive material and the second adhesive material may not generate repulsive force against each other. For example, the difference between the surface energy of the first adhesive material and the surface energy of the second adhesive material may be relatively small. Here, the range of polar energy among the surface energies of each of the first adhesive material and the second adhesive material may be within about 10 mN/m. The specific gravity of the first adhesive material and the specific gravity of the second adhesive material may be the same or similar.

The first part P1 of the adhesive member AM may have a first modulus, the second part P2 of the adhesive member AM may have a second modulus, and the third part P3 of the adhesive member AM may have a third modulus.

In an embodiment, the second modulus may be different from the first modulus, and the third modulus may be different from the first modulus and the second modulus. For example, the first modulus may have a range from greater than about 1 Mpa (i.e., may be equal to or greater than about 1 Mpa) and the second modulus may have a range from about 0.03 Mpa to about 1 Mpa. In other embodiments, each of the first modulus and the second modulus may have a range from about 0.03 Mpa to about 1 Mpa. However, embodiments of the disclosure are not limited thereto. The third modulus may vary depending on a mixing ratio of the first adhesive material and the second adhesive material in the third part P3 of the adhesive member AM.

For example, the first component CP1 may be the window member WN of FIG. 4, and the second component CP2 may be the window protection layer PL of FIG. 4. In this case, the adhesive member AM may be the first adhesive member AM1 of FIG. 4.

In other embodiments, the first component CP1 may be the polarizing member POL of FIG. 4 and the second component CP2 may be the window member WN of FIG. 4. In this case, the adhesive member AM may be the second adhesive member AM2 of FIG. 4.

For example, the first part P1 of the adhesive member AM may overlap a flat part of the display device DD of FIG. 4, and the second part P2 of the adhesive member AM may overlap a curved part of the display device DD of FIG. 4. The curved part refers to a part where buckling occurs in case that the display device DD is in a folded state. However, embodiments of the disclosure are not limited thereto.

However, the embodiments of the disclosure are not limited to this configuration, and the adhesive member AM may correspond to at least one of the first, second, third, fourth, and fifth adhesive members AM1, AM2, AM3, AM4, and AM5 of FIG. 4. The adhesive member AM may correspond to an adhesive member using an optically transparent resin in addition to the first, second, third, fourth, and fifth adhesive members AM1, AM2, AM3, AM4, and AM5 in the display device DD of FIG. 4.

The adhesive member AM is not limited to corresponding to the adhesive member used in the display device DD including the foldable area FA as shown in FIGS. 1, 2, 3, and 4, and the adhesive member AM may also be used in display devices that do not include the foldable area FA.

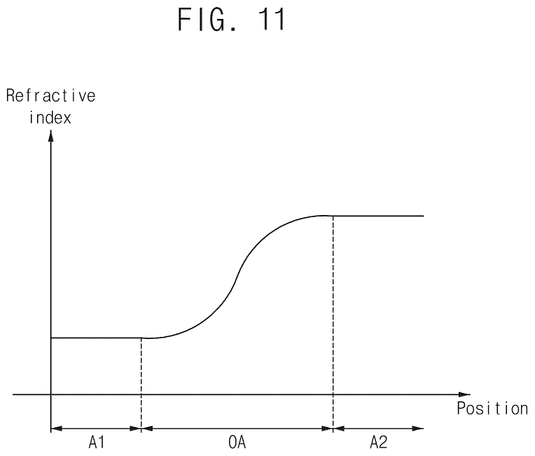

FIG. 11 is a schematic view illustrating the change in a refractive index according to a position of the adhesive member of FIG. 10.

Referring to FIGS. 10 and 11, in an embodiment, the refractive index of the third part P3 of the adhesive member AM may change continuously in a direction (i.e., the second direction D2 or a direction opposite to the second direction D2) from the first part P1 of the adhesive member AM toward the second part P2 of the adhesive member AM or the second part P2 of the adhesive member AM toward the first part P1 of the adhesive member AM. That is, in the overlapping area OA, the refractive index of the adhesive member AM may continuously change depending on the position. This continuous change in refractive index may be achieved by adjusting the amounts of application of the first adhesive material and the second adhesive material depending on the position of the adhesive member AM. Accordingly, appearance defects of the second component CP2 may be reduced in the overlapping area OA.

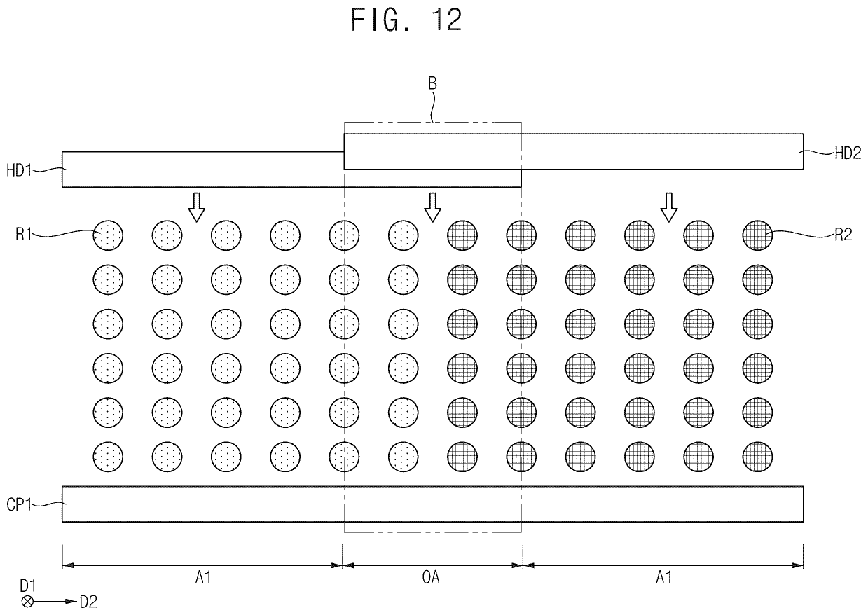

FIGS. 12, 13, and 14 are schematic cross-sectional views illustrating steps of a method for manufacturing a display device according to an embodiment of the disclosure.

The method for manufacturing the display device described with reference to FIGS. 12, 13, and 14 may represent a part of the method for manufacturing the display device DD described with reference to FIG. 4. For example, the method for manufacturing the display device described with reference to FIGS. 12, 13, and 14 may represent the method for forming the adhesive member AM of FIG. 10.

Referring to FIGS. 4, 10, and 12, the first component CP1 may be attached to the display panel DP including pixels. For example, the first component CP1 may correspond to the polarizing member POL or the window member WN of FIG. 4.

A first inkjet head HD1 and a second inkjet head HD2 may be disposed on the first component CP1. The first inkjet head HD1 may be disposed to overlap the first area A1 where the first part P1 of FIG. 10 is formed, and the second inkjet head HD2 may be disposed to overlap the second area A2 where the second part P2 of FIG. 10 is formed.

Each of the first inkjet head HD1 and the second inkjet head HD2 may include nozzles. Through the nozzles, a first adhesive material R1 in liquid form may be discharged from the first inkjet head HD1, and a second adhesive material R2 in liquid form different from the first adhesive material may be discharged from the second inkjet head HD2. For example, the first adhesive material R1 and the second adhesive material R2 may include an optically transparent resin. In an embodiment, the first adhesive material R1 and the second adhesive material R2 may be discharged simultaneously. That is, the first adhesive material R1 discharged through the first inkjet head HD1 and the second adhesive material R2 discharged through the second inkjet head HD2 may be applied simultaneously on the first component CP1.

The properties of matter of the first adhesive material R1 and the second adhesive material R2 are the same as the properties of matter of the first adhesive material R1 and the second adhesive material R2 described with reference to FIG. 10. Therefore, description thereof will be omitted.

In an embodiment, the first inkjet head HD1 and the second inkjet head HD2 may be disposed to partially overlap each other in the first direction D1. Specifically, the first inkjet head HD1 and the second inkjet head HD2 may be disposed to overlap in the first direction D1 in the overlap area OA where the third part P3 of FIG. 10 is formed. Accordingly, in the overlapping area OA, the first adhesive material R1 and the second adhesive material R2 may be mixed. In this case, in the overlap area OA, no step may be formed between the first adhesive material R1 and the second adhesive material R2 applied on the first component CP1, and the mixed B first adhesive material and the second adhesive material may have a substantially flat upper surface.

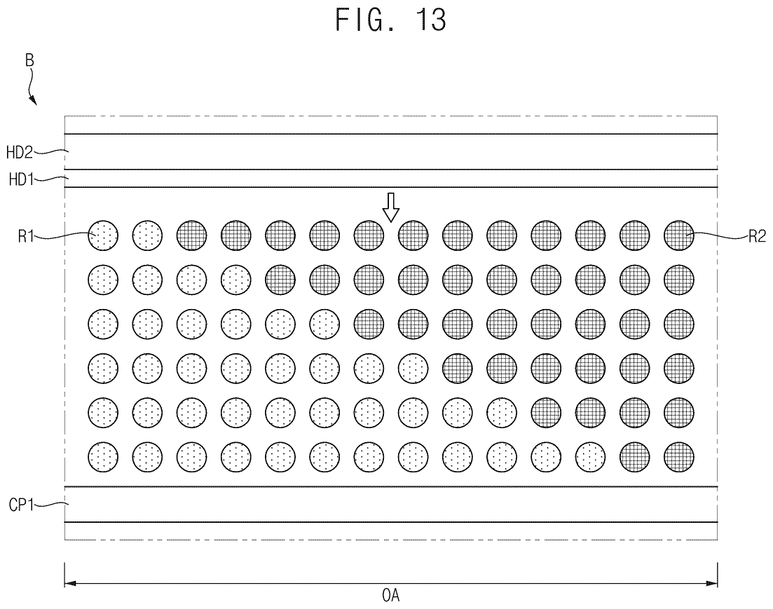

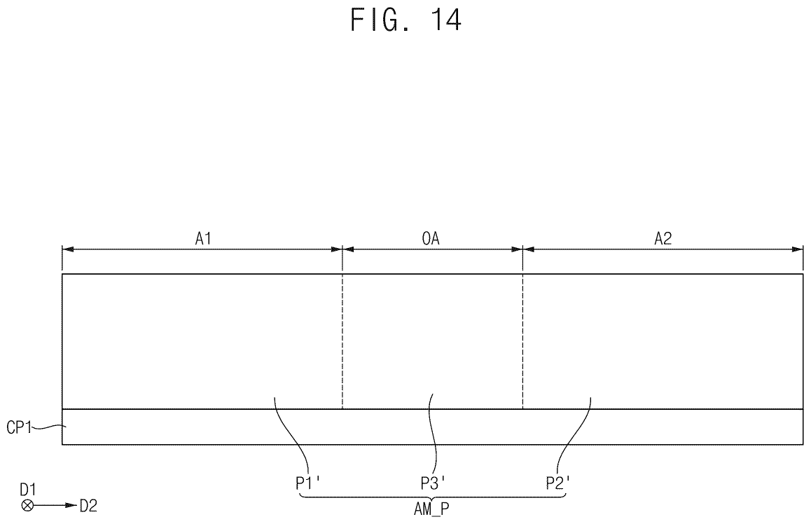

Referring to FIG. 13, in an embodiment, in the overlap area OA, the amount of application of the first adhesive material applied on the first component CP1 may change gradually in a direction (i.e., the second direction D2) from the first area A1 toward the second area A2, and the amount of application of the second adhesive material applied on the first component CP1 may change gradually in a direction (i.e., a direction opposite to the second direction D2) from the second area A2 toward the first area A1.

For example, in the overlap area OA, the amount of application of the first adhesive material applied on the first component CP1 may decrease gradually in the direction (i.e., the second direction D2) from the first area A1 toward the second area A2, and the amount of application of the second adhesive material applied on the first component CP1 may decrease gradually in the direction (i.e., a direction opposite to the second direction D2) from the second area A2 toward the first area A1. However, embodiments of the disclosure are not limited thereto.

Referring further to FIG. 14, by applying the first adhesive material and the second adhesive material on the first component CP1, a preliminary adhesive member AM_P including a first part P1′ overlapping the first area A1, a second part P2′ overlapping the second area A2, and a third part P3′ overlapping the third area A3 may be formed.

The second component CP2 of FIG. 10 may be bonded to the first component CP1 with the preliminary adhesive member AM_P between the second component CP2 and the first component CP1. The preliminary adhesive member AM_P (i.e., the first adhesive material and the second adhesive material applied on the first component CP1) may be cured by irradiating ultraviolet rays. Accordingly, the preliminary adhesive member AM_P may be hardened to form the adhesive member AM of FIG. 10.

Referring again to FIGS. 1, 2, 3, 4, 5, 6, 7, 8, 9, 10, 11, 12, 13, and 14, the display device DD according to embodiments of the disclosure may include the adhesive member AM attaching the first component CP1 and the second component CP2 disposed the display panel DP, and including: the first part P1 having the first modulus and including the first adhesive material, the second part P2 having the second modulus different from the first modulus and including the second adhesive material different from the first adhesive material, and the third part P3 located between the first part P1 and the second part P2, having the third modulus different from the first modulus and the second modulus, and including the first adhesive material and the second adhesive material. Accordingly, appearance defect of the second component CP2 attached to the first component CP1 may be reduced. Reliability defects of the display device DD may be reduced.

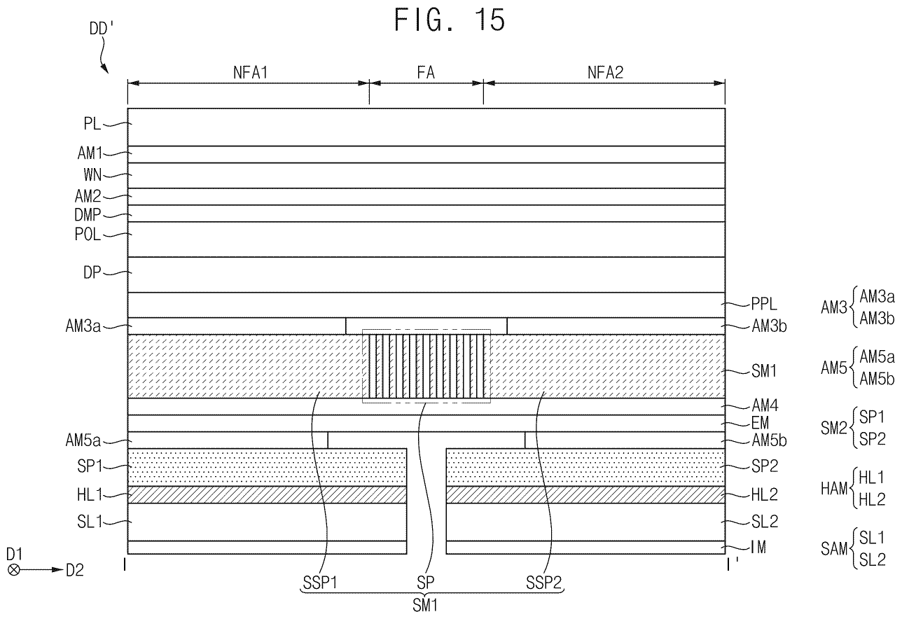

FIG. 15 is a schematic cross-sectional view illustrating another example of a cross-section taken along line I-I′ of FIG. 1.

Referring to FIG. 15, a display device DD′ according to an embodiment of the disclosure may include a window protection layer PL, a first adhesive member AM1, a window member WN, a second adhesive member AM2, a damping member DMP, a polarizing member POL, a display panel DP, a third adhesive member AM3, a first support member SM1, a fourth adhesive member AM4, an elastic member EM, a fifth adhesive member AM5, a second support member SM2, a heat dissipation member HAM, an impact absorbing member SAM, and an insulating member IM.

However, the display device DD′ described with reference to FIG. 15 may be substantially the same as or similar to the display device DD described with reference to FIG. 4 except for further including the damping member DMP. Therefore, hereinafter, overlapping descriptions will be omitted or simplified.

The damping member DMP may be disposed on the polarizing member POL. Specifically, the damping member DMP may be disposed between the polarizing member POL and the window member WN. The damping member DMP may protect the display panel DP from external shock. The damping member DMP may be implemented as a damping layer or a damping film. For example, the damping member DMP may include polyurethane, polyethylene, polypropylene, and the like. These can be used alone or in combination with each other.

The second adhesive member AM2 may be disposed between the damping member DMP and the window member WN. The second adhesive member AM2 may attach the buffer member DMP and the window member WN to each other. For example, the second adhesive member AM2 may include an optically clear adhesive or an optically transparent resin. In an embodiment, the second adhesive member AM2 may include an optically transparent resin.

At least one of the first, second, third, fourth, and fifth adhesive members AM1, AM2, AM3, AM4, and AM5 of FIG. 15 may correspond to the adhesive member AM of FIG. 10. In the display device DD′, in addition to the first, second, third, fourth, and fifth adhesive members AM1, AM2, AM3, AM4, and AM5, an adhesive member using an optically transparent resin may correspond to the adhesive member AM of FIG. 10.

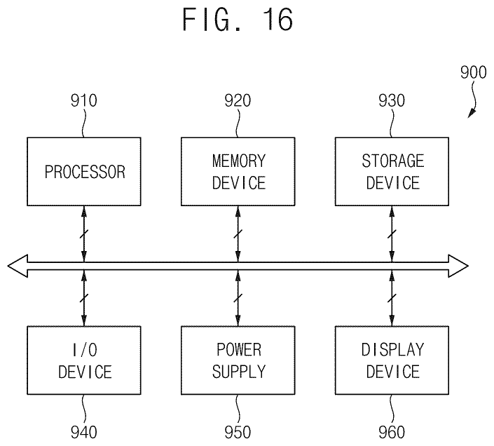

FIG. 16 is a schematic block diagram illustrating an electronic device according to an embodiment of the present disclosure.

Referring to FIG. 16, in an embodiment, an electronic device 900 may include a processor 910, a memory device 920, a storage device 930, an input/output device 940, a power supply 950, and a display device 960. In this case, the display device 960 may correspond to the display device DD and DD′ described with reference to FIGS. 1 to 15. The electronic device 900 may further include several ports capable of communicating with a video card, a sound card, a memory card, a USB device, and the like.

In an embodiment, the electronic device 900 may be implemented as a television. In another embodiment, the electronic device 900 may be implemented as a smart phone. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), and the like.

The processor 910 may perform certain calculations or tasks. The processor 910 may control the display device 960. In an embodiment, the processor 910 may be a microprocessor, a central processing unit (CPU), an application processor (AP), and/or the like. The processor 910 may be connected to other components through an address bus, a control bus, a data bus, and the like. The processor 910 may also be connected to an expansion bus, such as a peripheral component interconnect (PCI) bus.

The memory device 920 may store data necessary for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

The storage device 930 may include a solid state drive (SSD), a hard disk drive (HDD), a CD-ROM, and the like.

The input/output device 940 may include input means such as a keyboard, keypad, touch pad, touch screen, mouse, and the like and output means such as a speaker, a printer, and the like.

The power supply 950 may supply power necessary for the operation of the electronic device 900. The display device 960 may be connected to other components through buses or other communication links. In an embodiment, the display device 960 may be included in the input/output device 940.

The disclosure can be applied to various display devices. For example, the disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the disclosure. Accordingly, all such modifications are intended to be included within the scope of the disclosure. Therefore, it is to be understood that the foregoing is illustrative of various embodiments and is not to be construed as limited to the specific embodiments disclosed, and that modifications to the disclosed embodiments, as well as other embodiments, are intended to be included within the scope of the disclosure.

What is claimed is:

1. A display device, comprising:
a display panel including pixels;
a first component disposed on the display panel;
a second component disposed on the first component; and
an adhesive member between the first component and the second component and attaching the first component and the second component to each other, the adhesive member including:
a first part having a first modulus and including a first adhesive material;
a second part having a second modulus different from the first modulus and including a second adhesive material different from the first adhesive material; and
a third part located between the first part and the second part, having a third modulus different from the first modulus and the second modulus, and including the first adhesive material and the second adhesive material.

2. The display device of claim 1, wherein
the first modulus is equal to or greater than about 1 Mpa, and
the second modulus is in a range of about 0.03 Mpa to about 1 Mpa.

3. The display device of claim 1, wherein each of the first modulus and the second modulus is in a range of about 0.03 Mpa to about 1 Mpa.

4. The display device of claim 1, wherein a thickness of the adhesive member is in a range of about 30 micrometers (μm) to about 50 micrometers (μm).

5. The display device of claim 1, wherein a thickness of the adhesive member is in a range of about 35 micrometers (μm) to about 100 micrometers (μm).

6. The display device of claim 1, wherein a refractive index of the third part continuously changes in a direction from the first part toward the second part or from the second part toward the first part.

7. The display device of claim 1, wherein
the first component is a polarizing member, and
the second component is a window member.

8. The display device of claim 1, wherein
the first component is a window member, and
the second component is a window protection layer protecting the window member.

9. The display device of claim 1, further comprising:
a polarizing member between the display panel and the first component, wherein
the first component is a damping member protecting the display panel, and
the second component is a window member.

10. The display device of claim 1, wherein the first adhesive material and the second adhesive material include an optically transparent resin.

11. The display device of claim 1, wherein the display panel includes:
a flexible foldable area; and
a non-folding area adjacent to the foldable area.

12. A method for manufacturing a display device, the method comprising:
forming a display panel including pixels;
attaching a first component on the display panel;
simultaneously applying a first adhesive material and a second adhesive material different from the first adhesive material on the first component;
bonding a second component to the first component; and
forming an adhesive member by curing the first adhesive material and the second adhesive material applied on the first component, the adhesive member including:
a first part having a first modulus and including the first adhesive material;
a second part having a second modulus different from the first modulus and including the second adhesive material different from the first adhesive material; and
a third part located between the first part and the second part, having a third modulus different from the first modulus and the second modulus, and including the first adhesive material and the second adhesive material.

13. The method of claim 12, wherein in an overlapping area where the third part is formed,
an amount of application of the first adhesive material gradually changes in a direction from a first area where the first part is formed toward a second area where the second part is formed, and
an amount of application of the second adhesive material gradually changes in a direction from the second area toward the first area.

14. The method of claim 12, wherein
the first modulus is equal to or greater than about 1 Mpa, and
the second modulus is in a range of about 0.03 Mpa to about 1 Mpa.

15. The method of claim 12, wherein each of the first modulus and the second modulus is in a range of about 0.03 Mpa to about 1 Mpa.

16. The method of claim 12, wherein a refractive index of the third part continuously changes in a direction from the first part toward the second part or from the second part toward the first part.

17. The method of claim 12, wherein
the first component is a polarizing member, and
the second component is a window member.

18. The method of claim 12, wherein
the first component is a window member, and
the second component is a window protection layer protecting the window member.

19. The method of claim 12, further comprising:
disposing a polarizing member between the display panel and the first component, wherein
the first component is a damping member protecting the display panel, and
the second component is a window member.

20. The method of claim 12, wherein the display panel includes:
a flexible foldable area; and
a non-folding area adjacent to the foldable area.

21. An electronic device comprising:
a display device; and
a processor which controls the display device,
wherein the display device includes:
a display panel including pixels;
a first component disposed on the display panel;
a second component disposed on the first component; and
an adhesive member between the first component and the second component and attaching the first component and the second component to each other, the adhesive member including:
a first part having a first modulus and including a first adhesive material;
a second part having a second modulus different from the first modulus and including a second adhesive material different from the first adhesive material; and
a third part located between the first part and the second part, having a third modulus different from the first modulus and the second modulus, and including the first adhesive material and the second adhesive material.
